(19) United States
(12) Patent Application Publication
(10) Pub. No.: US 2015/0130042 A1
(43) Pub. Date: May 14, 2015

(54) SEMICONDUCTOR MODULE WITH RADIATION FINS

(71) Applicant: FUJI ELECTRIC CO., LTD., Kawasaki-shi (JP)

(72) Inventor: Kenichiro Sato, Shiojiri-shi (JP)

(73) Assignee: FUJI ELECTRIC CO., LTD., Kawashaki-shi (JP)

(21) Appl. No.: 14/372,162

(22) PCT Filed: Mar. 15, 2013
(86) PCT No.: PCT/JP2013/057381

§ 371 Date: Jul. 14, 2014

(30) Foreign Application Priority Data
Mar. 22, 2012 (JP) 2012-065253

(51) Int. Cl. H01L 25/07; H01L 23/367; H01L 23/31; H01L 23/10; H01L 23/29

(52) U.S. Cl. CPC H01L 25/072; H01L 23/10; H01L 23/293; H01L 23/3107; H01L 23/3675; H01L 23/3672
USPC 257/690

(57) ABSTRACT

A semiconductor module with radiation fins includes a semiconductor module including a metal base. The metal base has an outer circumferential portion surrounding the same and a top panel portion surrounded by the outer circumferential portion. One side of the top panel portion is disposed with a plurality of semiconductor chips through a plurality of corresponding insulating substrates and the other side of the top panel portion is disposed with radiation fins. The plurality of semiconductor chips is connected to electric wiring to electrically connect to the outside of the semiconductor module. A thickness of the top panel portion is less than a thickness of the outer circumferential portion. The top panel portion between the insulating substrates includes a groove having an opening narrower than a bottom portion. The plurality of semiconductor chips is sealed together with the groove by resin.

### TECHNICAL FIELD

The present invention relates to a semiconductor module with radiation fins for use in a power converter and the like.

### BACKGROUND ART

FIGS. 7 and 8(a), 8(b) each show a conventional power semiconductor module 200. FIG. 5 is a diagram showing an inverter circuit of a power converter in which the power semiconductor module 200 is used. FIG. 7 is a plan view of a metal base 101. The metal base 101 has radiation fins 110, as shown in FIG. 8(a). The metal base 101 also has three insulating substrates 108 on its upper surface, and two pairs of semiconductor chips configured by IGBTs 103 and FWDs 104, are soldered with metal foil pieces 105 to each of the three insulating substrates 108. The terms “IGBT” and “FWD,” which are described hereinafter, are short for “insulated gate bipolar transistor” and “free wheel diode,” respectively. The semiconductor chips shown in FIG. 7 are connected by an aluminum wire, not shown, or soldered to a wiring copper plate to configure a three-phase inverter circuit of U, V and W-phases shown in FIG. 5. The alphabet “M” shown in FIG. 5 represents a load of the exemplary three-phase inverter circuit and is not included in the three-phase inverter circuit itself. FIG. 8(a) is a cross-sectional diagram taken along the line A-A′ of FIG. 7, and FIG. 8(b) is an enlarged cross-sectional diagram of the broken line section of FIG. 8(a). The layers of semiconductor chips in the U, V and W-phases are sealed with resin (resin sealing) on the metal base together with insulating substrates and the bonding wires.

In the power semiconductor module 200 shown in FIGS. 7 and 8(a), 8(b), conduction-induced or switching-induced losses occur in the IGBTs (IGBT chips) 103 and FWDs (FWD chips) 104 during the operation of the power semiconductor module 200, causing the semiconductor chips to generate heat. If the junction temperatures of the semiconductor chips continue to increase to above the rated temperature due to this heat, then it results in damage to the elements, causing the semiconductor chips to run while cooling. The heat generated by the semiconductor chips is transmitted to the metal base 101 with the radiation fins 110 through solders 106 bonded to the rear surfaces of the semiconductor chips and the insulating substrates 108 therebelow, and is then released from the radiation fins 110 to the outside. In order to effectively cool the insulating substrates 108 bonded to the metal base 101 as well as the semiconductor chips, it is preferred that the metal base 101 with the radiation fins 110 be cooled using a cooling fluid, not shown.

Examples of the known technologies according to this type of power semiconductor module 200 with radiation fins 110 include the one disclosed in Patent Document 1.

Patent Document 1 discloses an insulated circuit board, a cooling structure therefor, a power semiconductor device, and a cooling structure therefor, which are designed for heat dissipation and use in a power semiconductor module. The configuration shown in FIGS. 7 and 8(a), 8(b) is obtained by combining the cooling structures disclosed in Patent Document 1 with the components of the three-phase inverter circuit configured by the U, V and W-phases.

Another known document discloses a technique for injecting epoxy resin to the semiconductor elements bonded to a metal base, to extend the life span of the bonding wires (Patent Document 2).

Patent Document 1: Japanese Patent Application Publication No. 2004-22914 (FIG. 1)

Patent Document 2: Japanese Patent Application Publication No. 2008-270455

### DISCLOSURE OF THE INVENTION

However, during the operation of the power semiconductor module 200 shown in FIGS. 7 and 8(a), 8(b), the operation-induced heat causes thermal interference between the closely-situated IGBT 103 and FWD 104 on each insulating substrate 108 or between the closely-situated insulating substrates 108. As a result, the temperature of the semiconductor chips disposed in the middle tends to rise.

For example, because all of the semiconductor chips generate heat during the operation of the power semiconductor module 200 shown in FIGS. 7 and 8(a), 8(b), thermal interference occurs among the three closely-situated insulating substrates 108 shown in FIG. 7. In reaction to this thermal interference from the both sides, especially the insulating substrate 108 corresponding to, for example, the V-phase in the middle and the semiconductor chips soldered thereto tend to become hot. This leads to a restriction in the operating temperature of the power semiconductor module 200 due to the semiconductor chips in the middle. Moreover, due to the repeated changes in the temperatures of the three insulating substrates 108 of the U, V and W-phases on the metal base 101, which are associated with the operation of the power semiconductor module 200, the soldered parts crack. Cracks in the solders in the power semiconductor module 200 impede efficient transmission of the heat of the semiconductor chips to the radiation fins 110. In addition, ununiformity in temperature throughout the semiconductor chips corresponding to the three phases, i.e., the U, V, and W-phases, together with the thermal changes associated with the operation of the power semiconductor module 200, causes peeling of the sealing resin from the front surface of the metal base 101.

The present invention was contrived in view of the points described above. In order to solve these problems, the object of the present invention is to provide, at low cost, a highly reliable semiconductor module with radiation fins that is capable of reducing the thermal resistance with its excellent radiation performance and is configured to reduce the thermal interference between a plurality of semiconductor chips and prevent the sealing resin from peeling from the metal base.

The present invention can accomplish this object by providing a semiconductor module having a metal base, wherein the metal base has an outer circumferential portion surrounding the same and a top panel portion surrounded by the outer circumferential portion. One side of the top panel portion is disposed with a plurality of semiconductor chips via a plurality of corresponding insulating substrates and the other side is disposed with radiation fins. The plurality of semiconductor chips is connected to electric wiring to electrically connect to the outside of the semiconductor module. A thickness of the top panel portion is less than a thickness of the outer circumferential portion. The top panel portion has a groove disposed between the plurality of semiconductor chips. The plurality of semiconductor chips is sealed together with the groove by resin.

It is preferred that the semiconductor module with radiation fins further has a terminal case fixed to the outer circumferential portion of the metal base with an interior of the resin case being sealed by the resin. In the semiconductor module with radiation fins, it is more preferred that the resin for sealing the interior of the terminal case is epoxy resin. In the semiconductor module with radiation fins, it is also preferred that the top panel portion further has a groove on the outside of the plurality of semiconductor chips disposed thereon via the plurality of corresponding insulating substrates.

In the semiconductor module with radiation fins, it is preferred that the cross-sectional shape of the groove is any one from the group consisting of a V-shape, a rectangular shape, or a semi-circular shape.

The present invention can provide, at low cost, a highly reliable semiconductor module with radiation fins that is capable of reducing the thermal resistance with its excellent radiation performance and is configured to inhibit the generation of solder cracks associated with thermal stress that a product receives during its operation.

The above and other objects, features and advantages of the present invention will become more evident based on the following description together with the accompanying drawings illustrating the preferred embodiments of the present invention.

### BRIEF DESCRIPTION OF THE DRAWINGS

FIG. 1 is a plan view showing insulating substrates and semiconductor chips soldered to a metal base of a semiconductor module with radiation fins according to the present invention.

FIG. 2 is a bottom view showing the back of the metal base of the semiconductor module with radiation fins according to the present invention.

FIG. 3 is a cross-sectional diagram of the semiconductor module with radiation fins according to the present invention, taken along the line B-B′ of FIG. 1.

FIG. 4(a) is a cross-sectional diagram of the semiconductor module with radiation fins according to the present invention taken along the line C-C′ of FIG. 1, and FIG. 4(b) is an enlarged cross-sectional diagram of the broken line section of FIG. 4(a).

FIG. 5 is a diagram showing an inverter circuit of a power converter in which this power semiconductor module is used.

FIGS. 6(a)-6(c) are cross-sectional diagrams of the semiconductor module with radiation fins according to the present invention taken along the line C-C′ showing another example of the cross-sectional shape of a concave portion provided between insulating substrates.

FIG. 7 is a plan view showing insulating substrates and semiconductor chips soldered onto a metal base of a conventional semiconductor module with radiation fins.

FIG. 8(a) is a cross-sectional diagram of the conventional semiconductor module with radiation fins taken along the line A-A′ of FIG. 1, and FIG. 8(b) is an enlarged cross-sectional diagram of the broken line section of FIG. 8(a).

FIG. 9 is a cross-sectional diagram of the semiconductor module with radiation fins according to a second embodiment of the present invention, the diagram corresponding to FIG. 3 showing the first embodiment.

FIG. 10 is a cross-sectional diagram of the semiconductor module with radiation fins according to the second embodiment of the present invention, the diagram corresponding to FIG. 4(a) showing the first embodiment.

### BEST MODE FOR CARRYING OUT THE INVENTION

The embodiments of a semiconductor module (power semiconductor module) with radiation fins according to the present invention are described hereinafter in detail with reference to the drawings. Note that the same reference numerals are used to indicate the corresponding configurations in the following description of the embodiments and accompanying drawings; thus, the overlapping explanations are omitted accordingly. The accompanying drawings described in the embodiments are merely to facilitate the understanding of the present invention and therefore are not necessarily illustrated based on accurate scales or dimensional ratios. The present invention should not be construed as being limited to the following embodiments so long as the gist of the present invention is not exceeded.

### First Embodiment

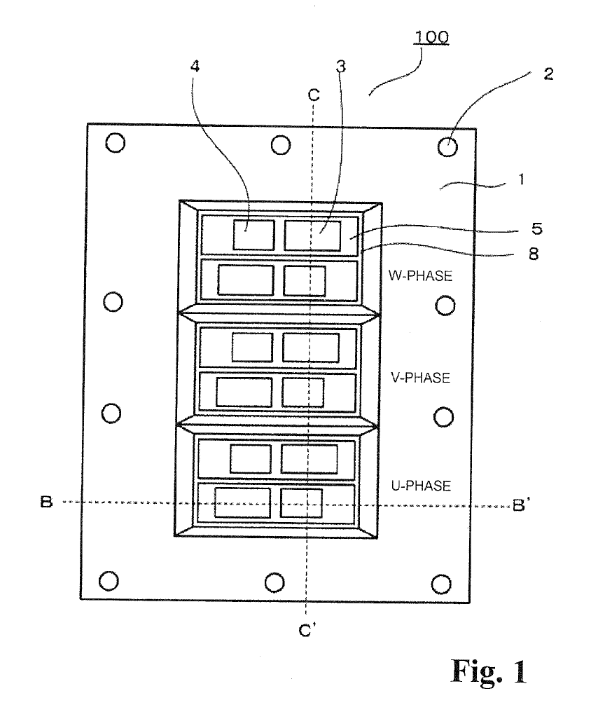

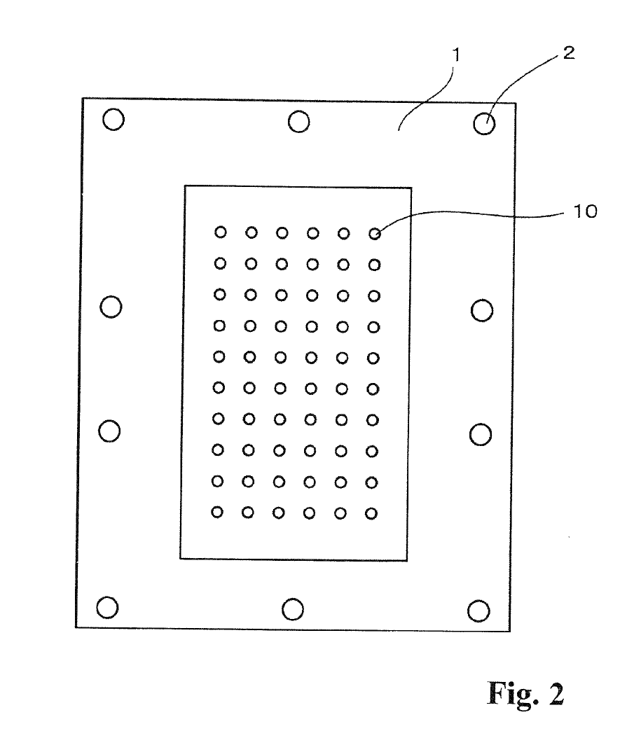

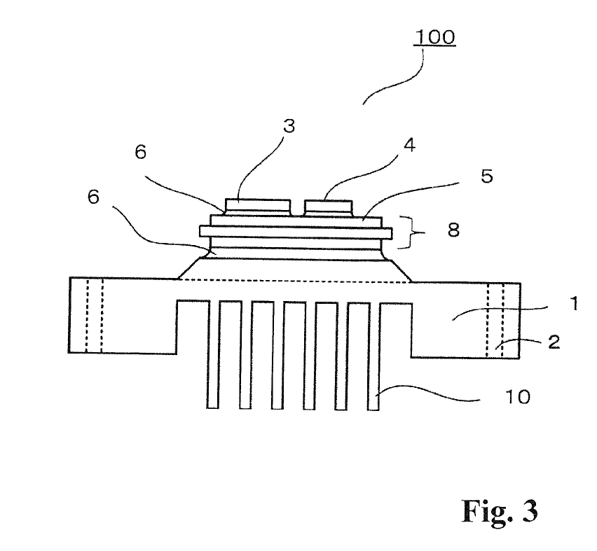

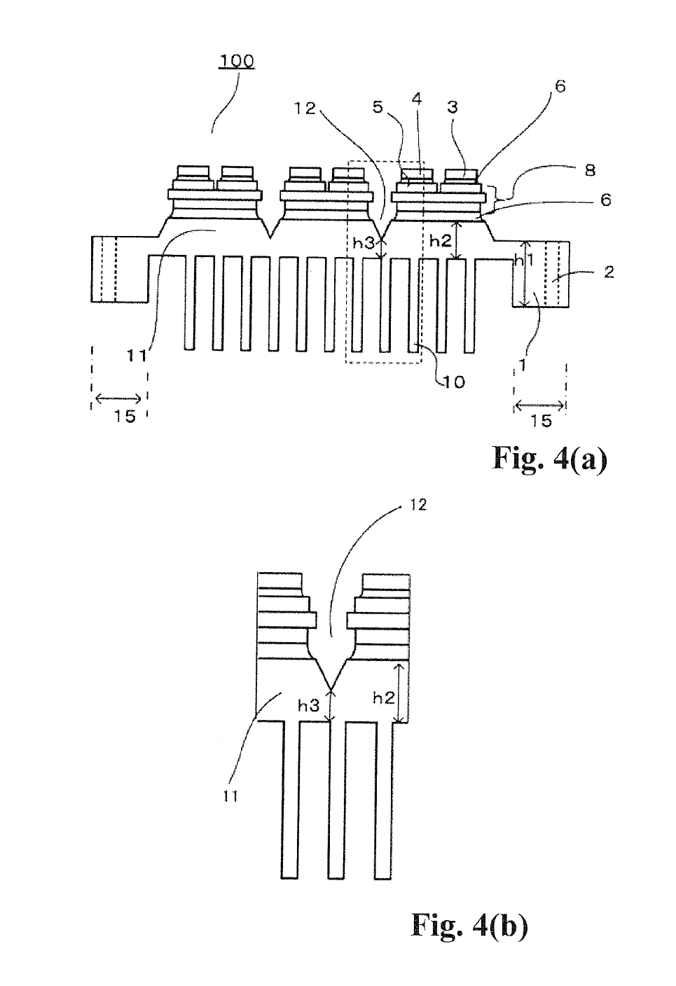

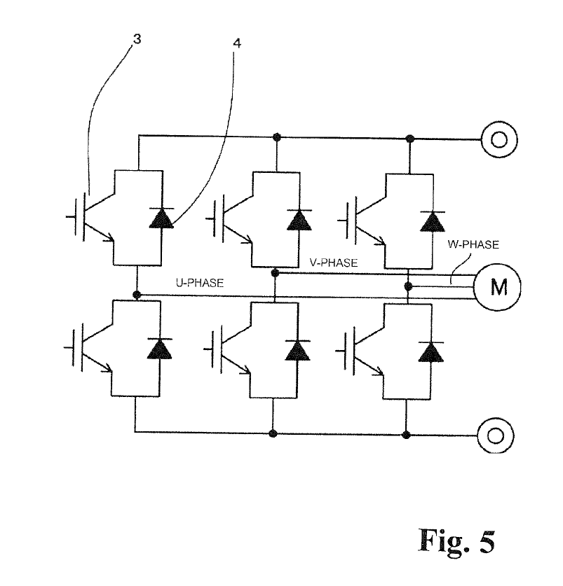

FIGS. 1 to 4(b) show a power semiconductor module 100 with radiation fins 10 according to the present invention. FIG. 5 is a diagram of an inverter circuit of a power converter, i.e., an analogous circuit of the power semiconductor module 100. FIG. 1 is a plan view showing insulating substrates 8, semiconductor chips and the like soldered onto a metal base 1. FIG. 2 is a bottom view showing the radiation fins of the power semiconductor module, which is the back of the metal base 1. FIG. 3 is a cross-sectional diagram taken along the line B-B′ of FIG. 1. FIG. 4(a) is a cross-sectional diagram taken along the line C-C′ of FIG. 1. FIG. 4(b) is an enlarged cross-sectional diagram showing the broken line section of FIG. 4(a).

The power semiconductor module 100 is now described in detail with reference to FIGS. 1 to 4(b). The power semiconductor module 100 has the metal base 1, an outer circumferential portion (flange portion) of which has mounting holes 2 for attaching the power semiconductor module 100 to an external device with nuts and screws. The power semiconductor module 100 has a structure in which semiconductor chips (IGBT chip 3, FWD chip 4) are soldered to a metal foil piece 5 on the front surface of each insulating substrate 8 by solder 6, and the insulating substrate 8 with the semiconductor chips soldered thereto by solder 6 is soldered to the front surface of the metal base 1 having the radiation fins 10. Note that, for the purpose of facilitating the understanding of the internal structure, these diagrams omit the illustration of metal wires for electrically connecting the semiconductor chips on the metal base 1, external connection terminals for inputting/outputting electric signals, a resin material for sealing these components, as well as a terminal case surrounding the sealing resin. For the convenience of explanation, the parts mounted on the respective insulating substrates 8 soldered to the metal base 1 are referred to as “U-phase semiconductor unit,” “V-phase semiconductor unit,” and “W-phase semiconductor unit,” respectively.

The metal base 1 is a metal plate of copper, aluminum, or alloy thereof with high thermal conductivity, and has the radiation fins 10 on its back that are disposed at the positions corresponding to the positions of the semiconductor chips on the front surface. FIG. 2 shows the positions or arrangement of a plurality of the pin-type, protruding radiation fins 10 on the back of the metal base 1; however, the radiation fins may be in a polygonal shape, a blade-like shape, a corrugated shape, or the like.

The insulating substrates 8 are each a ceramic plate or an insulating metal plate covered with an insulating film, with its entire rear surface (the side bonded to the metal base 1) having a metal foil piece and the front surface having a metal foil piece with a required wiring pattern. The materials used in the ceramic plate may be alumina, aluminum nitride, silicon nitride, and other ceramic materials. The metallic materials used in the insulating metal plate may be aluminum alloy. The semiconductor chips (e.g., the IGBT chips 3, FWD chips 4) are soldered to predetermined positions on the metal foil piece on the front surface of each insulating substrate 8.

Although not shown in FIGS. 1 to 4(b), in this power semiconductor module 100 a resin-molded terminal case is adhered to the front surface of an outer circumferential portion 15 of the metal base, the terminal case having an external connection terminal for inputting/outputting external signals integrally therein.

The semiconductor chips are soldered to the metal foil piece 5, machined into a wiring pattern, on the front surface of each insulating substrate 8. The group of semiconductor chips in the U-phase, V-phase and W-phase semiconductor units on the respective three insulating substrates 8 shown in FIG. 1, is disposed so as to correspond to the three phases of the U-phase, V-phase and W-phase semiconductor units configuring a three-phase inverter circuit, as shown in FIG. 5. The upper electrodes of these semiconductor chips are electrically connected to a lower end portion of the external connection terminal or to its vicinity by metal wires, to configure the three-phase inverter circuit shown in FIG. 5. The external connection terminal is integrally resin-molded with the terminal case. The electrical connection of the upper electrodes of the semiconductor chips may be performed by soldering a plate of aluminum alloy or copper alloy instead of using metal wires. Thin wires made of aluminum, copper, gold or alloy thereof are used as the metal wires, which are then bonded by ultrasound. The terminal case, not shown, is filled with sealing resin such as silicone gel or epoxy resin. Note that the sealing resin is preferably epoxy resin for being able to enhance the adhesion between the resin and the front surface of the metal base.

One of the characteristics of the power semiconductor module 100 of the present invention shown in the cross-sectional diagrams in FIGS. 4(a) and 4(b), is that the thickness h2 of a top panel portion 11 of the metal base 1 with radiation fins 10 is thinner than the thickness h1 of the outer circumferential portion 15. Another characteristic of the present invention is that the thickness h3 at the bottom portion (the deepest portion) of each groove 12 of the top panel portion 11 between the plurality of closely-situated insulating substrates 8 is thinner than the thickness h2 of the section other than each groove 12 of the top panel portion 11.

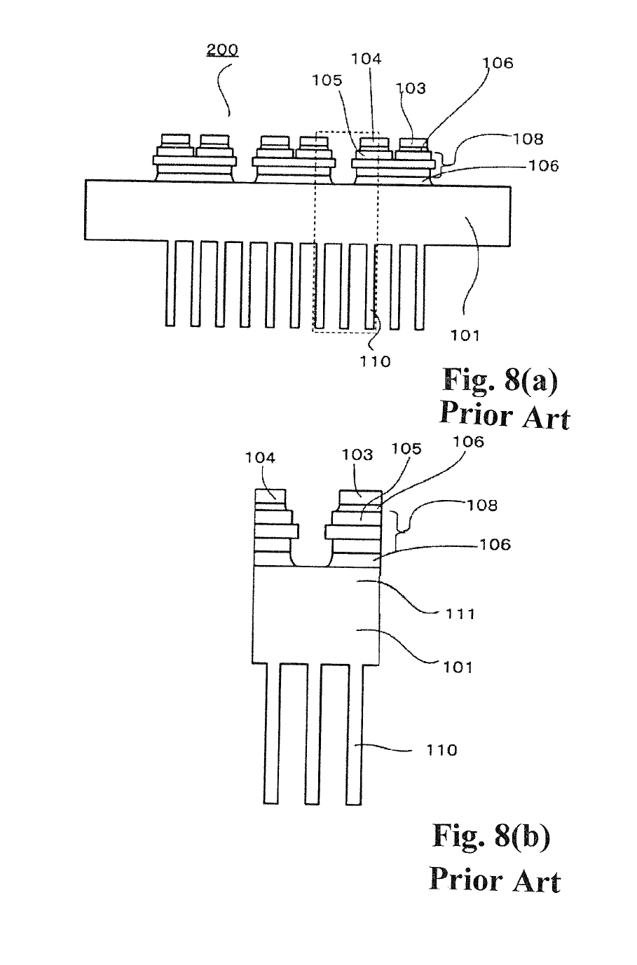

In the conventional metal base 101 with radiation fins 110, on the other hand, a top panel portion 111 and the outer circumferential portion have the same, uniform thickness, as shown in FIG. 8(b). Generally, the outer circumferential portion of this type of semiconductor module is provided with mounting holes for attaching the power semiconductor module to an external device with nuts and screws, where great tightening force is applied. For this reason, the thicknesses of the outer circumferential portion cannot be a predetermined thickness or less that corresponding to the force (e.g., the thickness that is thick enough that the metal base plate of the outer circumferential portion is not distorted by the tightening force of the screws).

For the thickness of the metal base 1, on the other hand, the thickness h2 of the top panel portion 11 can be set at 3 to 5 mm, the thickness h1 of the outer circumferential portion 15 at 4 to 6 mm, and the thickness h3 at the bottom portion of each groove 12 at 2 to 4 mm. The width of each groove 12 can be set at 1 to 3 mm and the depth at 1 to 3 mm.

Because the metal base 1 with radiation fins 10 releases the heat of the semiconductor chips to the cooling fluid, the thinner the top panel portion 11, the lower the thermal resistance can be. The thermal resistance is expressed by Formula (1).

Thermal resistance Rth=Thickness L of top panel portion of metal base plate/(Soldered area S of top panel portion of metal base plate×Thermal conductivity λ of metal base plate) (1)

Lowering the thermal resistance Rth in the formula (1) can improve the heat dissipation as expressed in the following formula (2) and lowers the temperature of the semiconductor chips, resulting in improvement of long-term reliability of the semiconductor module.

Temperature difference AT between semiconductor chips and cooling fluid=Thermal resistance Rth from semiconductor chips to cooling fluid×Loss W in semiconductor chips (2)

According to these formulae (1) and (2), the semiconductor module 100 with radiation fins 10 of the present invention can reduce the thermal resistance Rth during the actual operation and hence the temperature of the semiconductor chips by making the thickness h2 of the top panel portion 11 less than the thickness h1 of the outer circumferential portion 15.

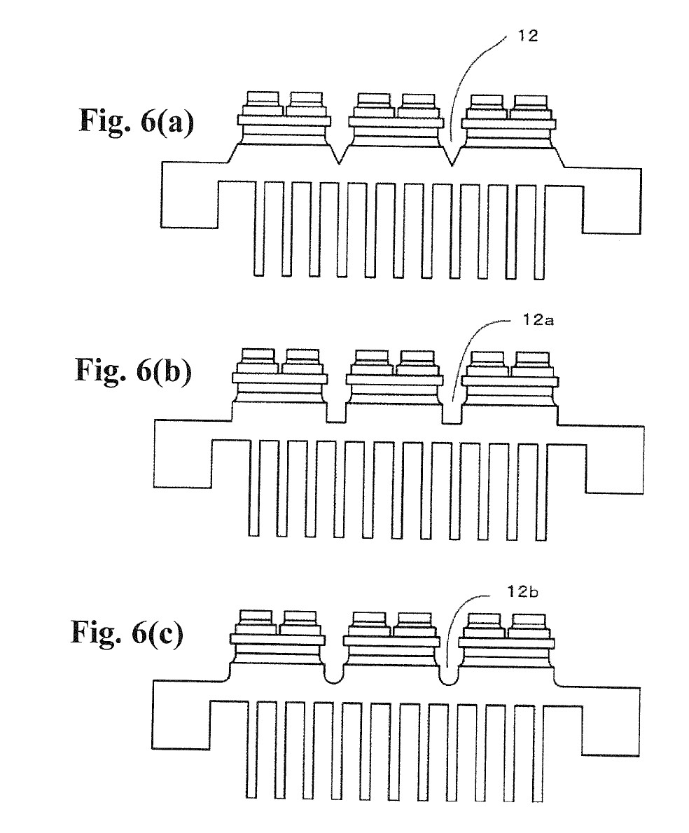

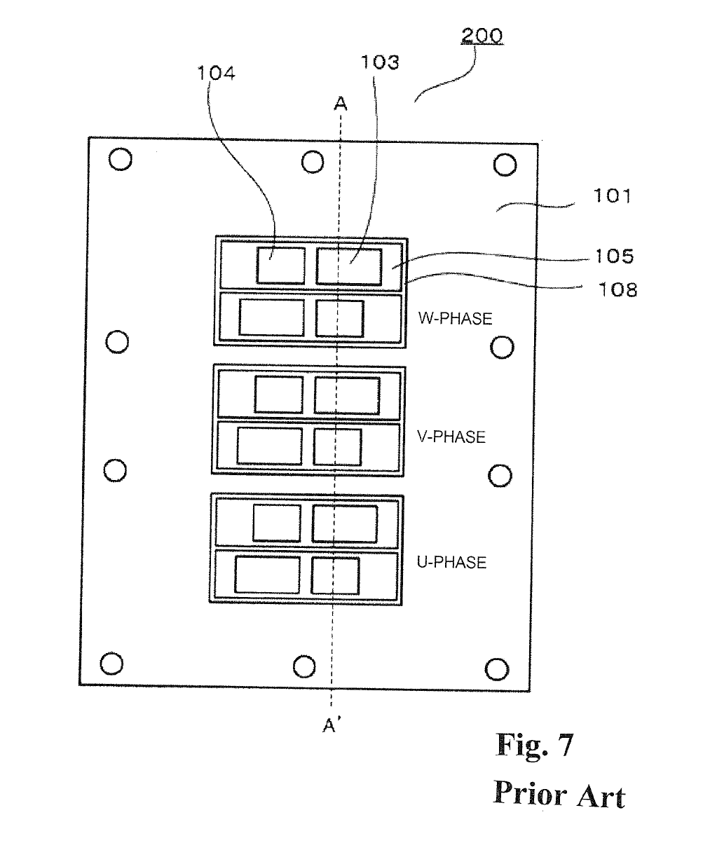

In addition, the top panel portion 11 is provided with a V-shaped groove 12 which is configured between the closely-situated insulating substrates 8 in such a manner that the thickness h2 of the top panel portion 11 is greater than the thickness h3 at the bottom portion of each groove 12. Providing these grooves 12 can prevent the transmission of heat between the adjacent insulating substrates 8 in the metal base, thereby reducing not only the thermal interference between the insulating substrates 8 but also particularly the temperature of the semiconductor chips on the middle insulating substrate 8 which are susceptible to thermal interference. Although it is possible to reduce the thermal interference even if the front surface of the metal base is flat and has no grooves between the insulating substrates 8 as long as the space between the insulating substrates 8 is wide enough, this kind of configuration results in an increase in the area of the metal base and therefore is not preferred in terms of achieving cost-effectiveness and compact size. Reduction in thermal resistance between the semiconductor units can lead to uniform temperature across the semiconductor units, which eventually leads to a gentle thermal gradient in the metal base, inhibiting the occurrence of solder cracks. As described above, the grooves 12 are formed between the three, closely-situated insulating substrates 8 on the front surface of the metal base 1. The shape of the grooves can be not only the cross-sectional V-shape of the grooves 12 in FIG. 6(a), but also the other concave shapes complying with the gist of the present invention, such as FIG. 6(b) the rectangular shape of grooves 12a and FIG. 6(c) the semi-circular shape of grooves 12b, as shown in FIGS. 6(a)-6(c).

One of the benefits of forming the grooves into these concave shapes according to the present invention is that, when sealing the whole structures of the semiconductor chips on the metal base 1 with, for example, epoxy resin, the adhesion strength between the epoxy resin and the front surface of the metal base 1 can be enhanced because the superficial area of the front surface of the metal base 1 with the grooves 12 becomes greater than that of the flat surface without the grooves. Filling up the grooves 12, the epoxy resin does not easily peel off, which is another expected benefit of the present invention. As far as the resin for obtaining these benefits concerned, it is preferable to use epoxy resin instead of gel-type resin because epoxy resin is stronger and provides higher compression strength when used for sealing. To further enhance the benefit of preventing the resin from peeling easily, the width of the opening of each groove may be made narrower than that of the bottom portion so that the resin gets caught in the internal structures of the grooves and compressed more, preventing the occurrence of cracks in the semiconductor chips and the soldered parts. Due to the effects of improving the adhesion strength of the epoxy resin and preventing this resin from peeling easily, the stress added to the soldered parts as a result of thermal changes can be lowered, preventing deterioration of the semiconductor module associated with the occurrence of solder cracks, improving the reliability of the semiconductor module, and extending the life span of the semiconductor module. Note that a well-known molding method such as cutting, forging, and metal injection molding methods can be used as a method for molding the metal base with radiation fins.

The above has described the example where the three semiconductor units corresponding to the U, V and W-phases are disposed; however, the effects of the present invention can be accomplished as long as there are two or more semiconductor units disposed in a semiconductor module.

### Second Embodiment

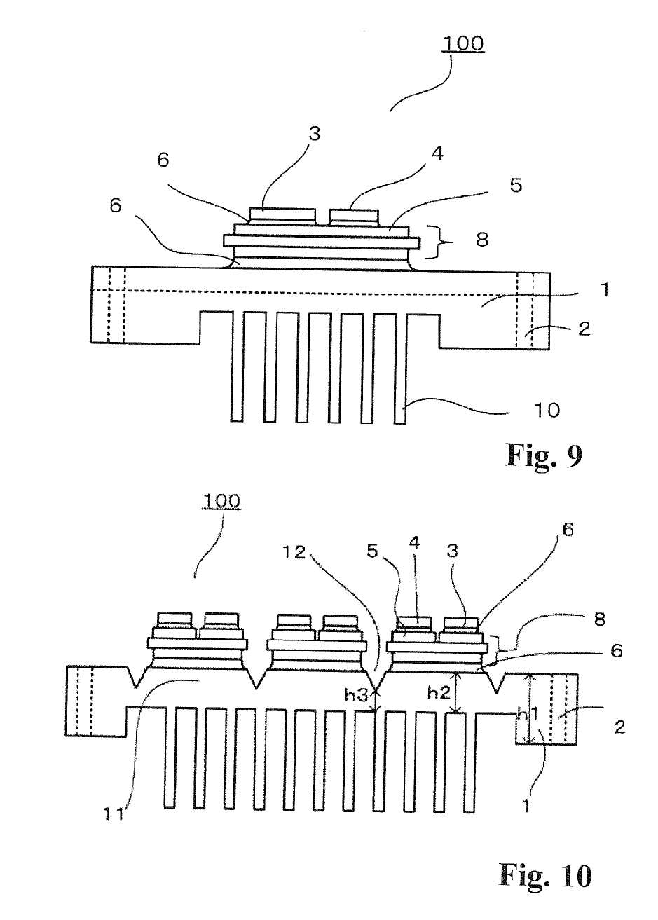

The second embodiment of the present invention is described with reference to FIGS. 9 and 10. FIGS. 9 and 10 are cross-sectional diagrams showing a semiconductor module corresponding to the one shown in FIGS. 3 and 4(a) according to the first embodiment. The second embodiment is different from the first embodiment in that the grooves 12 are provided on the outside of the farthest semiconductor units. Providing the grooves on the outside as described above has the effect of firmly fixing the sealing resin to the metal base. It is preferred that the sealing resin be epoxy resin.

The above description merely illustrates the principles of the present invention. A person skilled in the art can make various modifications and changes; thus, the present invention is not limited to the precise configurations and applications illustrated and described above. Therefore, all corresponding modifications and equivalents are deemed to fall within the scope of the present invention defined by the appended claims and equivalents thereof.

### EXPLANATION OF REFERENCE NUMERALS

1 Metal base

2 Mounting hole

3 IGBT chip

4 FWD chip

5 Metal foil piece

6 Solder

8 Insulating substrate

10 Radiation fin

11 Top panel portion

12 Groove

15 Outer circumferential portion

h1 Thickness of outer circumferential portion

h2 Thickness of top panel portion

h3 Thickness at bottom portion of groove

1. A semiconductor module with radiation fins, comprising:
a semiconductor module including a metal base,
wherein the metal base has an outer circumferential portion surrounding the same and a top panel portion surrounded by the outer circumferential portion, and one side of the top panel portion is disposed with a plurality of semiconductor chips through a plurality of corresponding insulating substrates and the other side of the top panel portion is disposed with radiation fins,
the plurality of semiconductor chips is connected to electric wiring to electrically connect to outside of the semiconductor module,
a thickness of the top panel portion is less than a thickness of the outer circumferential portion,
the top panel portion between the insulating substrates has a groove,
the groove has an opening narrower than a bottom portion, and
the plurality of semiconductor chips is sealed by resin together with the groove.

2. The semiconductor module with radiation fins according to claim 1, further comprising:
a terminal case fixed to the outer circumferential portion of the metal base,
wherein the plurality of semiconductor chips and the groove are sealed inside the terminal case with the resin.

3. The semiconductor module with radiation fins according to claim 1, wherein the resin is epoxy resin.

4. The semiconductor module with radiation fins according to claim 1, wherein the top panel portion further comprises a groove on an outer side of the plurality of semiconductor chips disposed thereon via the plurality of insulating substrates.

5. A semiconductor module with radiation fins, comprising:
a semiconductor module including a metal base,
wherein the metal base has an outer circumferential portion surrounding the same and a top panel portion surrounded by the outer circumferential portion, and one side of the top panel portion is disposed with a plurality of semiconductor chips via a plurality of corresponding insulating substrates and the other side of the top panel portion is disposed with radiation fins,
the plurality of semiconductor chips is connected to electric wiring to electrically connect to the outside of the semiconductor module,
a thickness of the top panel portion is less than a thickness of the outer circumferential portion,
the top panel portion between the insulating substrates is formed with a groove,
a cross-sectional shape of the groove is any one from a group including a v-shape, a rectangular shape, or a semi-circular shape, and
the plurality of semiconductor chips is sealed by resin together with the groove.
